(19) United States
(12) Patent Application Publication
(10) Pub. No.: US 2009/0065819 A1
(43) Pub. Date: Mar. 12, 2009

(54) APPARATUS AND METHOD OF MANUFACTURE FOR AN IMAGER STARTING MATERIAL

(76) Inventor: Bedabrata Pain, Los Angeles, CA (US)

Correspondence Address: Zilka-Kotab, PC, P.O. BOX 721120, SAN JOSE, CA, 95172-1120, US

(21) Appl. No.: 11/947,627

(22) Filed: Nov. 29, 2007

Related U.S. Application Data
(60) Provisional application No. 60/861,688, filed on Nov. 29, 2006.

(51) Int. Cl. H01L 27/146; H01L 29/00; H01L 31/18

(52) U.S. Cl. 257/291; 257/506; 438/57; 257/E29.001; 257/E27.133

(57) ABSTRACT

An imager apparatus and associated starting material are provided. Such starting material includes a first silicon layer and an oxide layer disposed adjacent to the first silicon layer. Further included is a first doped layer disposed adjacent to the oxide layer with a first doping, and a second doped layer disposed adjacent to the first doped layer with, a second doping that is less than the first doping layer.

### RELATED APPLICATIONS

The present application claims the benefit of a provisional application fried on Nov. 29, 2006 under application Ser. No. 60/861,688, which is incorporated herein by reference in its entirety for all purposes.

### STATEMENT REGARDING FEDERALLY SPONSORED RESEARCH OR DEVELOPMENT

The invention described herein was made in die performance of work tinder a NASA contract, and is subject to the provisions of Public Law 96-517 (35 USC 202) in which the Contractor has elected to retain title.

### FIELD OF THE INVENTION

The present invention relates to optical sensors such as imagers, and more particularly to starting materials utilized for manufacturing imagers.

### BACKGROUND

Imaging puts an extraordinary pressure on interface quality, since a good quality imager can detect a few electrons of a signal. The presence of defects, impurities, dangling bonds, etc. at a silicon-silicon dioxide interface of an imager act as charge tops, resulting in reduced photo-conversion efficiency and increased dark current both of which degrade imager performance.

One known way to prevent such charge traps from degrading imager performance involves holding the aforementioned interface at a fixed potential in equilibrium, so that, there is no net charge generation or recombination. This process is called passivation of the interface traps.

For a back-illuminated CMOS imager, preventing unwanted potential gradients at the silicon interface facing the light gathering side is critical, since it can simultaneously reduce photo-conversion efficiency and increase dark current. In order to hold this interface area at a fixed potential or to provide the correct potential gradient, the doping concentration may be increased in this region. However, for imaging purposes, the silicon device layer requires low-doping. Thus, very high doping may be desired at the interface, and low-doping is desired in the device area.

One way of introducing a high density of doping (e.g. Boron, etc.) is to implant the desired doping in the silicon device layer through the buried oxide layer before it is bonded to an associated handle silicon wafer. Although it is easy to introduce a heavily doped thin layer using this approach, it is difficult to generate an ideal profile. Such difficulty arises from the fact that, water-to-wafer bond activation requires a high temperature anneal (e.g. 1100 C for 2-4 hours) for forming permanent bonds.

Unfortunately, such thermal anneal will, cause the implanted doping to diffuse away from the surface, simultaneously reducing the interlace doping concentration and increasing the concentration in the silicon device layer. Both of these affects are unwanted from the imaging point of view that requires exactly the opposite, namely high doping concentration at the interface for trap passivation, and low doping concentration in the silicon device layer for improved photo-collection.

There is thus a need for addressing these and/or other issues associated with the prior art.

### SUMMARY

An imager apparatus and associated starting material are provided. Such starting material includes a first silicon layer and an oxide layer disposed adjacent to the first silicon layer. Further included is a first doped layer disposed adjacent to the oxide layer with a first doping, and a second doped layer disposed adjacent to the first doped layer with a second doping that is less than the first doping layer.

### BRIEF DESCRIPTION OF THE DRAWINGS

FIG. 1 illustrates a method for manufacturing a starter material and a resultant imager, in accordance with one embodiment.

FIGS. 2A-2I illustrate various stages of processing, in accordance with the method of FIG. 1.

FIG. 3 illustrates a cross-section of a resultant imager apparatus, in accordance with one embodiment.

### DETAILED DESCRIPTION

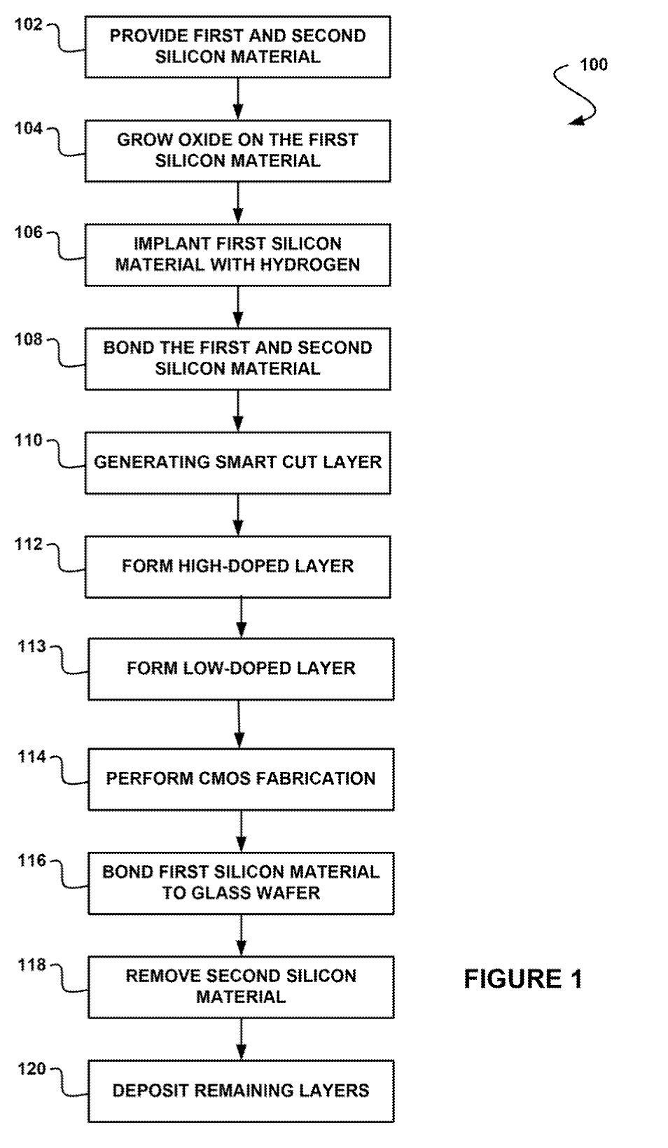

FIG. 1 illustrates a method 100 for manufacturing a starter material and a resultant imager, in accordance with, another embodiment. As shown, a first silicon material (e.g. device silicon wafer, etc.) and a second silicon material (e.g. support/handle silicon wafer, etc) are provided. See operation 102.

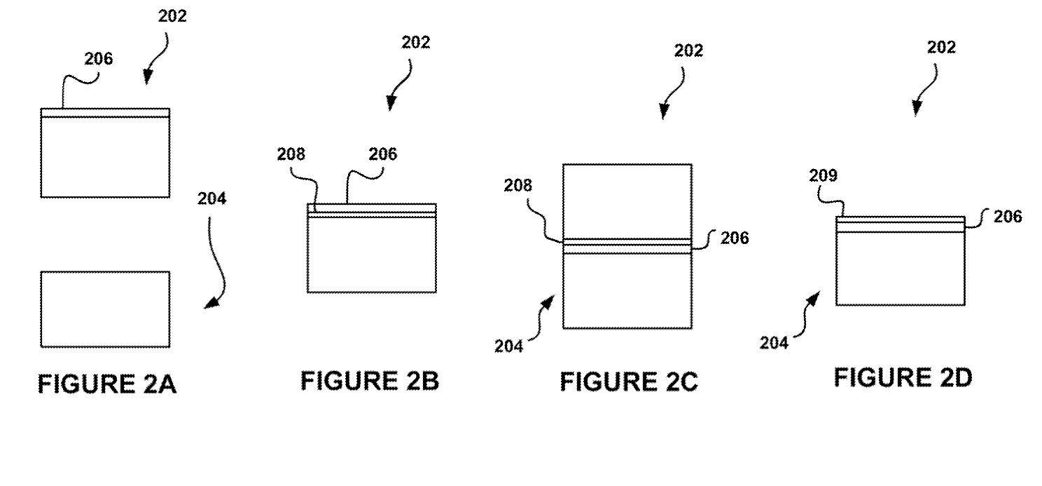

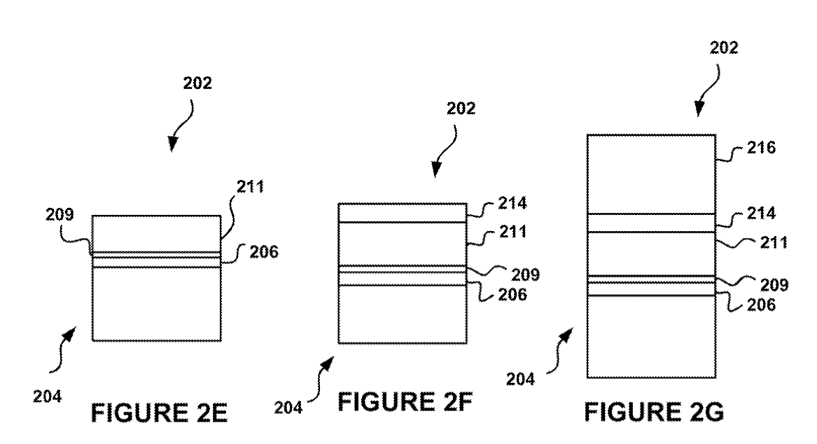

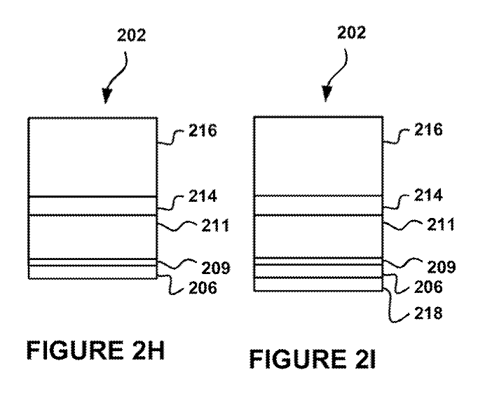

Thereafter, an oxide is grown on the first silicon material, as shown in operation 104. In one embodiment, such oxide may exhibit enhanced purity. For example, such oxide layer may be thermally grown to minimize oxide stress and interface trap density, etc. FIG. 2A illustrates a first silicon material 202 and a second silicon material 204 with an oxide layer 206 being formed on the first silicon material 202. Such oxide layer 206 may thus provide a buried- or bulk-oxide (BOX) layer, as shown.

Next, in operation 106, hydrogen may be implanted in the first silicon material, in use, such implanted ions are adapted to penetrate the oxide grown in operation 104. FIG. 2B illustrates the first silicon material 202 with a hydrogen implantation layer 208. As will soon become apparent, such hydrogen implantation, acts as an atomic scalpel in a subsequent smart cut process, allowing for thin slices of monocrystalline film to be sheared from the silicon material, etc.

Turning now to operation 108, the first and second silicon material are bonded. In various embodiments, this may be accomplished utilizing a heated bonding process, or any other desired process, for that matter. Specifically, in one embodiment, the first and second silicon materials may undergo low temperature oxide-to-silicon, bonding, thereby forming a buried oxide structure with a top layer taking the form of a silicon device layer. In use, such low temperature bonding may be followed by a higher temperature annealing process.

Next, a smart cut process is carried out to provide a smart cut layer. See operation 110, FIG. 2C illustrates the first and second silicon material 202, 204 bonded to each other, while FIG. 2D shows the first silicon material 202 after the aforementioned smart cut process is carried out to provide a smart cut wafer with a silicon device layer 209 with the underlying oxide layer 206. It should be noted that the silicon device layer 209 may be doped to a certain extent and thus may form a first doped layer.

It should be noted that the smart cut process may include any process capable of producing the smart cut layer. For example, such process may involve a bubble formation operation involving the first silicon material, followed by a break away operation, polishing (e.g. chemical-mechanical), etc. for removing at least a portion of the first silicon material.

While not shown, the silicon device layer may be further doped. See operation 112. In various optional embodiments, the silicon device layer may be further doped to provide a first doping that is greater than 1×10¹⁶/cm³, 1×10¹⁷/cm³, 1×10¹⁸/cm³, 1×10¹⁹/cm³, etc. The amount of such doping in operation 112 may depend on the amount of doping already present after the smart cut operation of operation 110. While the further doping of operation 112 is shown in FIG. 1 to be a separate operation subsequent to the smart cut operation of operation 110, it should be noted that a desired amount of doping may be provided during operation 110, or in any other desired manner.

In one embodiment, such doping may be carried out utilizing a diffusion process. In another embodiment, such doping may be carried out utilizing implantation. Of course, in other embodiments, various other techniques may be employed.

In one embodiment, the first doping of the silicon device layer may include a heavily doped p-type semiconductor material. Of course, however, other types (e.g. n-type, etc.) are contemplated. Further, while further not shown, a thermal oxide may be resident between the silicon device layer and the underlying oxide layer.

By applying the doping in operation 112 subsequent to the heated bonding of operation 108 and associated annealing process, such doping is less likely to be affected by any heat from the bonding, in one embodiment, this technique may result in the doping maintaining a desired elevated concentration profile by avoiding affects of the thermal anneal process of operation 108 which would otherwise cause the implanted doping diffuse away from the surface, simultaneously reducing the interface doping concentration and increasing the concentration in the silicon device layer.

With continuing reference to FIG. 1, a second doped layer is formed adjacent to the silicon device layer with a second doping that is less than the first doping layer. Note operation 113. FIG. 2E shows the first silicon material 202 after the aforementioned second doped layer 211 is formed.

In various optional embodiments, the second doped layer may be doped with a second doping that is less than 1×10¹⁷/cm³, 1×10¹⁴/cm³, 1×10¹³/cm³, 1×10¹²/cm³, etc. Further, the second doping may be less than the first doping by any degree. Just by way of example, the second doping may be less than the first doping by at least a magnitude of two, three, or more.

In one embodiment, the second doped layer may include an epitaxial silicon layer, in an optional embodiment, such doping may be carried out by growing such layer directly on the silicon device layer. Of course, other techniques may very well be used, in different embodiments. Further, similar to the silicon device layer, the second doped layer may include a heavily-doped p-type semiconductor material. Of course, however, other types (e.g. n-type, etc.) are contemplated.

As an option, the first doped silicon device layer may be equipped with a first thickness, and the second doped layer may have a second thickness greater than the first thickness. For example, the first doped layer may have a thickness of 0.1 um, while the second doped layer may have a thickness that is multiple orders greater in magnitude.

In use, the aforementioned epitaxial silicon may be grown at a much lower temperature and has a much lower thermal budget (e.g. compared with that of a water-to-wafer bonding and annealing process, etc). Therefore, diffusion of Boron away from the interface and into the silicon may be prevented at least in part, providing improved interface passivation and minimizing photo-generation loss. Moreover, such technique allows for flexibility of using additional optimized thermal anneal to generate an ideal doping profile. Furthermore, epitaxial silicon may be of better quality than usual float zone materials, providing improved imaging performance. Therefore, the present process may, in some embodiments, provide an ideal starting material for high performance back-illuminated complimentary metal-oxide semiconductor (CMOS) imager implementation.

With continuing reference to FIG. 1, a CMOS fabrication process is then carried out, per operation 114. In one possible embodiment, a bulk CMOS process flow may be used to generate a plurality of CMOS imagers through implantation, oxidation, ILD, metal deposition, and/or patterning at the wafer level. It should be noted that any bulk CMOS process may be used. For example, a bulk CMOS process may be optimized for imaging. By this process, various structures may be formed including, but not limited to a deep semiconductor well, MOSFETs, capacitors, and/or other devices. FIG. 2F shows the first silicon material 202 after the aforementioned CMOS process, where the resultant structure includes an inter-layer dielectric (ILD) 214 as shown.

In operation 116, the first silicon material is bonded to a glass or silicon wafer for mechanical support. Further, in operation 118, the second silicon material is removed, through mechanical grinding, wet etching, and/or reactive ion etching (RIE), for example. FIG. 2G illustrates the first silicon material 204 being bonded to a glass or silicon wafer or other substrate 216, and FIG. 2H illustrates the second silicon material 206 being removed, at least in part.

Thereafter, an arm-reflection layer (ARC) layer is deposited. See operation 120 and item 218 in FIG. 2I. Such ARC layer is capable of providing improved optical coupling through a suppression of reflection at the silicon material/oxide (e.g. Si—SiO₂, etc.) interface.

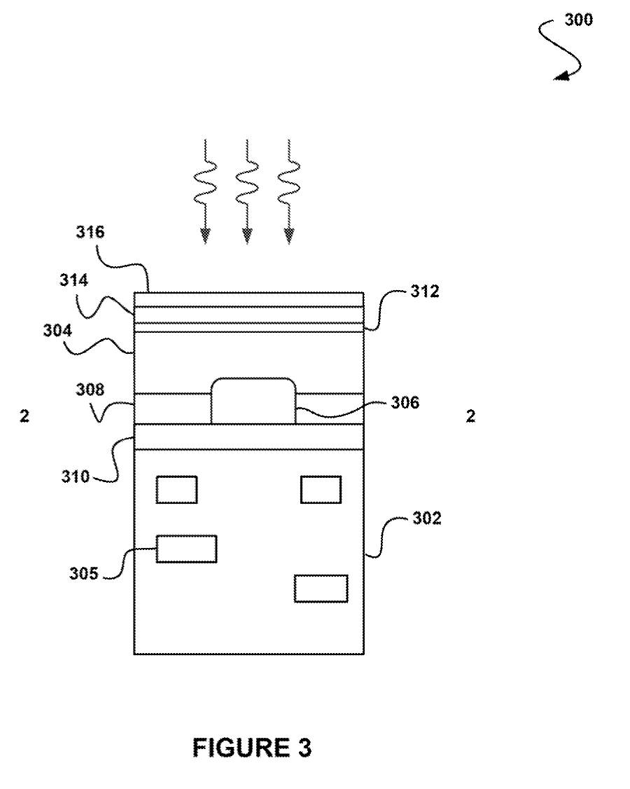

FIG. 3 illustrates a cross-section of an imager apparatus 300, in accordance with one embodiment. As an option, the imager apparatus 300 may be manufactured utilizing the method 100 of FIG. 1. Further, the definitions provided above may equally apply to the present description.

In the present embodiment, the imager apparatus 300 may include a back-illuminated imager. While the imager apparatus 300 shown in FIG. 3 may represent a single imager pixel, it should be noted that an array of such pixels may be provided, in different embodiments.

Still yet, such imager apparatus 300 may be manufactured utilizing CMOS technology. Of course, however, other types of imager apparatuses, manufacturing processes, etc. are contemplated. For example, the imager apparatus 300 may also take the form of a charge coupled device (CCD) imager.

As shown, an ILD 302 is provided which is formed on the silicon wafer. Also included a silicon layer 304 of a first conductivity type acting as a junction anode. In use, such silicon layer 304 is adapted to convert light to photoelectrons. As further shown, metal layers 305 may be provided for interconnection of circuits and photo-detectors fabricated on the silicon layer (combined 304, 306, 308). Such metal layers 305 are separated and protected by the ILD 302. In one optional embodiment, the ILD 302 may extend a depth of 10 micrometers, or any other desired depth, for example.

Also included is a semiconductor well 306 of a second conductivity type formed in the silicon layer 304 for acting as a junction cathode. In one embodiment, the first conductivity type may include a p-type conductivity, and the second conductivity type may include an n-type conductivity. Of course, other embodiments are contemplated where the first conductivity type may include an n-type conductivity, and the second conductivity type may include a p-type conductivity, Still yet, in one embodiment, the semiconductor well 306 may take the form of a deep implanted n-well but, of course, may take other forms as well (such as a stacked layers of n-type and p-type implants, etc.).

Further provided is an implant region 308 of the first conductivity type disposed about the semiconductor well 306 and just above an oxide layer 310 that resides between the silicon layer 304 and the ILD 302, in the manner shown. Disposed over the silicon layer 304 is a passivation layer 312 of the first conductivity type. Such implant region 308 and the passivation layer 312 may, in one embodiment, be more heavily doped with respect to the silicon layer 304, for reasons that will soon become apparent. Further, during use, the passivation layer 312 may serve a variety of purposes, examples of which will be set forth hereinafter in the context of different embodiments.

Disposed over the passivation layer 312 is an ARC 314. Also, one or more color filter layers 316 may be disposed over the anti-reflection layer 314. Again, see FIG. 3.

In one possible embodiment, the apparatus 300 may represent one of a multiplicity of devices that are configured in a system array. An illustrative example of such system array may be found with reference to U.S. Patent Application Publication No.: 2006/0076590A1 filed Sep. 13, 2005, which is incorporated herein by reference in its entirety for all purposes. Of course, such exemplary system array is set forth for illustrative purposes only and should not be construed as limiting in any manner whatsoever.

The foregoing description has set forth only a few of the many possible implementations. For this reason, this detailed description is intended by way of illustration, and not by way of limitations. Variations and modifications of the embodiments disclosed herein may be made based on the description set forth herein, without departing from the scope and spirit of the present application.

It is only the following claims, including all equivalents, that are intended to define the scope of the various embodiments. Moreover, the embodiments described above are specifically contemplated to be used alone as well as in various combinations. Accordingly, other embodiments, variations, and improvements not described herein are not necessarily excluded.

What is claimed is:

1. A starting material, comprising:
a first silicon layer;
an oxide layer disposed adjacent to the first silicon layer;
a first doped layer disposed adjacent to the oxide layer with a first doping; and
a second doped layer disposed adjacent to the first doped layer with a second doping that is less than the first doping layer.

2. The starting material of claim 1, wherein first doped layer includes a silicon device layer.

3. The starting material of claim 1, wherein the second doping is less than the first doping by at least a magnitude of two.

4. The starting material of claim 1, wherein the second doping is less than the first doping by at least a magnitude of three.

5. The starting material of claim 1, wherein the first doping is greater than 1×10¹⁶/cm³.

6. The starting material of claim 1, wherein the second doping is less than 1×10¹⁵/cm³.

7. The starting material of claim 1, wherein the first doped layer has a first thickness, and the second doped layer has a second thickness greater than the first thickness.

8. The starting material of claim 1, wherein the first silicon material is bonded with a second silicon material.

9. The starting material of claim 1, wherein the second doped layer includes an epitaxial silicon layer.

10. A method for manufacturing an imager, comprising:
providing a starting material including:
a first silicon layer,
an oxide layer disposed adjacent to the first silicon layer,
a first doped layer disposed adjacent to the oxide layer with a first doping, and
a second doped layer disposed adjacent to the first doped layer with a second doping that is less than the first doping layer; and
manufacturing an imager utilizing the starting material.

11. The method of claim 10, wherein first doped layer includes a silicon device layer.

12. The method of claim 10, wherein the second doping is less than the first doping by at least a magnitude of two.

13. The method of claim 10, wherein the second doping is less than the first doping by at least a magnitude of three.

14. The method of claim 10, wherein the first doping is greater than 1×10¹⁶/cm³.

15. The method of claim 10, wherein the second doping is less than 1×10¹⁵/cm³.

16. The method of claim 10, wherein the first doped layer has a first thickness, and the second doped layer has a second thickness greater than the first thickness.

17. The method of claim 10, wherein the second doped layer is formed after the first silicon material is bonded with a second silicon material.

18. An imager manufactured utilizing a process, comprising:
providing a starting material including:
a first silicon layer,
an oxide layer disposed adjacent to the first silicon layer,
a first doped layer disposed adjacent to the oxide layer with a first doping, and
a second doped layer disposed adjacent to the first doped layer with a second doping that is less than the first doping layer, and
manufacturing an imager utilizing the starting material.

19. The imager of claim 18, wherein the imager includes a charge coupled device (CCD) imager or a charge injection device (CID).

20. The imager of claim 18, wherein the imager includes a complimentary metal-oxide semiconductor (CMOS) imager.

21. The imager of claim 18, wherein the oxide layer is thermally grown.
